(19) United States
(12) Patent Application Publication
(10) Pub. No.: US 2019/0198100 A1
(43) Pub. Date: Jun. 27, 2019

(54) CONDUCTIVE BRIDGE RESISTIVE RANDOM ACCESS MEMORY CELL

(71) Applicant: Intel Corporation, Santa Clara, CA (US)

(72) Inventors: Ravi Pillarisetty, Portland, OR (US); Prashant Majhi, San Jose, CA (US); Elijah V. Karpov, Portland, OR (US); Niloy Mukherjee, Beaverton, OR (US); James S. Clarke, Portland, OR (US)

(73) Assignee: Intel Corporation, Santa Clara, CA (US)

(21) Appl. No.: 16/329,202

(22) PCT Filed: Sep. 30, 2016
(86) PCT No.: PCT/US2016/054668

§ 371 Date: Feb. 27, 2019

(51) Int. Cl. G11C 13/00; H01L 45/00; H01L 27/24

(52) U.S. Cl. CPC G11C 13/0011; H01L 45/085; H01L 45/124; G11C 2013/0083; H01L 45/146; H01L 27/2463; H01L 45/1266

(57) ABSTRACT

Substrates, assemblies, and techniques for enabling a resistive random access memory cell are disclosed herein. For example, in some embodiments, a device may include a top electrode, a modulated interfacial region, and a bottom electrode. The thickness of the modulated interfacial region can be modulated between an on state thickness and an off state thickness and the bottom electrode is an active electrode that is a source for metal ions for the creation of a filament between the top electrode and the bottom electrode. In an example, the filament is created when the transistor is in an on state and the filament is not present when the transistor is in an off state.

### CROSS-REFERENCE TO RELATED APPLICATION

This application is a national stage application under 35 U.S.C. § 371 of PCT International Application Serial No. PCT/US2016/054668, filed on Sep. 30, 2016 and entitled “CONDUCTIVE BRIDGE RESISTIVE RANDOM ACCESS MEMORY CELL,” which is hereby incorporated by reference herein in its entirety.

### TECHNICAL FIELD

The present disclosure relates generally to the field of memory cells, and more particularly, to conductive bridge resistive random access memory.

### BACKGROUND

Most, if not all, logic devices require some type of random access memory. Resistive random access memory (RRAM or ReRAM) is a type of non-volatile (NV) random-access computer memory that works by changing the resistance across a dielectric solid-state material. RRAM can be similar to a memristor which is a hypothetical, non-linear, passive two-terminal electrical component relating electric charge and magnetic flux linkage. The memristor's electrical resistance is not constant but depends on the history of current that had previously flowed through the device. Its present resistance depends on how much electric charge flowed in what direction it in the past. A RRAM cell is a device that remembers its history so when the electric power supply is turned off, the RRAM cell remembers its most recent resistance until it is turned on again. Using this property, the RRAM cell can be used as a memory cell or memory array for electronic devices.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a simplified block diagram illustrating an embodiment of a portion of an electronic device, in accordance with one embodiment of the present disclosure;

FIG. 2 is a simplified block diagram illustrating an embodiment of a portion of an electronic device, in accordance with one embodiment of the present disclosure;

FIG. 3A is a simplified block diagram illustrating an embodiment of a portion of an electronic device, in accordance with one embodiment of the present disclosure;

FIG. 3B is a simplified block diagram illustrating an embodiment of a portion of an electronic device, in accordance with one embodiment of the present disclosure;

FIG. 4 is a simplified graph illustrating example details associated with an embodiment of an electronic device, in accordance with one embodiment of the present disclosure;

FIG. 5 is a simplified block diagram diagram illustrating example details associated with an embodiment of a portion of an electronic device, in accordance with one embodiment of the present disclosure;

FIG. 6 is an interposer implementing one or more of the embodiments disclosed herein; and

FIG. 7 is a computing device built in accordance with an embodiment disclosed herein.

The figures of the drawings are not necessarily drawn to scale, as their dimensions can be varied considerably without departing from the scope of the present disclosure.

### DETAILED DESCRIPTION

The following detailed description sets forth example embodiments of apparatuses, methods, and systems relating to a communication system for device pairing in a local network. Features such as structure(s), function(s), and/or characteristic(s), for example, are described with reference to one embodiment as a matter of convenience; various embodiments may be implemented with any suitable one or more of the described features.

In the following description, various aspects of the illustrative implementations will be described using terms commonly employed by those skilled in the art to convey the substance of their work to others skilled in the art. However, it will be apparent to those skilled in the art that the embodiments disclosed herein may be practiced with only some of the described aspects. For purposes of explanation, specific numbers, materials and configurations are set forth in order to provide a thorough understanding of the illustrative implementations. However, it will be apparent to one skilled in the art that the embodiments disclosed herein may be practiced without the specific details. In other instances, well-known features are omitted or simplified in order not to obscure the illustrative implementations.

Disclosed herein are substrates, assemblies, and techniques for enabling a device that includes one or more resistive random access memory cells. In some embodiments, the device may include a source, a gate, and a drain. The source, the gate, and the drain can be on top of a support substrate such as a semiconductor substrate. In an implementation, the substrate may be a non-silicon flexible substrate.

Various operations will be described as multiple discrete operations, in turn, in a manner that is most helpful in understanding the embodiments disclosed herein, however, the order of description should not be construed to imply that these operations are necessarily order dependent. In particular, these operations need not be performed in the order of presentation.

The terms “over,” “under,” “below,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

Implementations of the embodiments disclosed herein may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. In other examples, the substrate may be a flexible substrate including 2D materials such as graphene and MoS2, organic materials such as pentacene, transparent oxides such as IGZO poly/amorphous (low temperature of dep) III-V semiconductors and Ge/Si, and other non-silicon flexible substrates. Although a few examples of materials from which the substrate may be formed are described here, any material that may serve as a foundation upon which a semiconductor device may be built falls within the spirit and scope of the embodiments disclosed herein.

In the following detailed description, reference is made to the accompanying drawings that form a part hereof wherein like numerals designate like parts throughout, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments. For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous. As used herein, the terms “chip” and “die” may be used interchangeably.

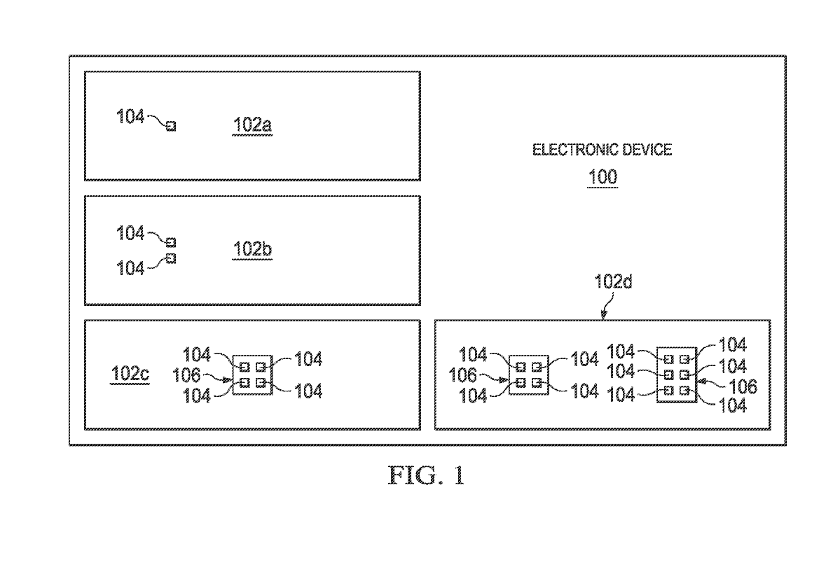

FIG. 1 is a simplified block diagram of an electronic device 100 that includes one or more resistive random access memory (RRAM) cells and arrays in accordance with an embodiment of the present disclosure. Electronic device 100 can include one or more electronic elements 102a-102d. Electronic device 100 can be any electronic device that includes memory (e.g., computer, smartphone, laptop, desktop, Internet-of-Things device, vehicle, handheld electronic device, personal digital assistant, wearable, etc.). Each electronic element 102a-102d can include a transistor 104 and/or one or more transistor arrays 106. Each transistor array 106 can be is a systematic arrangement of a plurality of transistors 104, (e.g., in rows and columns). Each transistor 104 can include a RRAM cell. Transistor 104 can be a transistor or an electronic switch that can be either in an “on” or “off” state and the term “transistor” includes a bipolar junction transistor (BJT), filed effect transistor (FET), finFET, junction gate FET (JFET), insulated gate FET (IGFET), metal-oxide-semiconductor field-effect transistors (MOSFET), n-channel field effect transistor (NFET) insulated-gate bipolar transistor, or other similar transistor that can be configured to perform the functions, features, and operations disclosed herein.

RRAM (or ReRAM) is a type of non-volatile (NV) random-access computer memory that works by changing the resistance across a dielectric solid-state material. Filamentary and interfacial RRAMs are strong contenders for RRAM addressing emerging embedded nonvolatile memory (e-NVM) needs. However, current filamentary based RRAMs suffer from variability due to a stochastic nature of the filament formation and breakage. In addition, current interfacial RRAM suffer from high on and off resistances at scaled dimensions making it relatively slow and requiring high voltages to switch from off to on. What is needed is stacking sequence that combines interfacial and filamentary mechanisms by using a dual stack of resistive and conductive oxides in combination with an active electrode for an ion source to circumvent the poor variability and high voltages with low switching speed issues.

Transistor 104 can be configured to resolve these issues (and others). For example, transistor 104 can be configured such that the switching mechanism of the RRAM combines the attributes of filamentary and interfacial RRAM. This allows for a stacking sequence that combines interfacial and filamentary features and mechanisms by using a dual stack of resistive and conductive oxides in combination with an active electrode for an ion source to circumvent the poor variability of filamentary RRAM and high voltages of interfacial RAM with low switching speed issues. In addition, the stacking sequence can be extended for a wide range of operating conditions and thus making it also applicable to storage class memories.

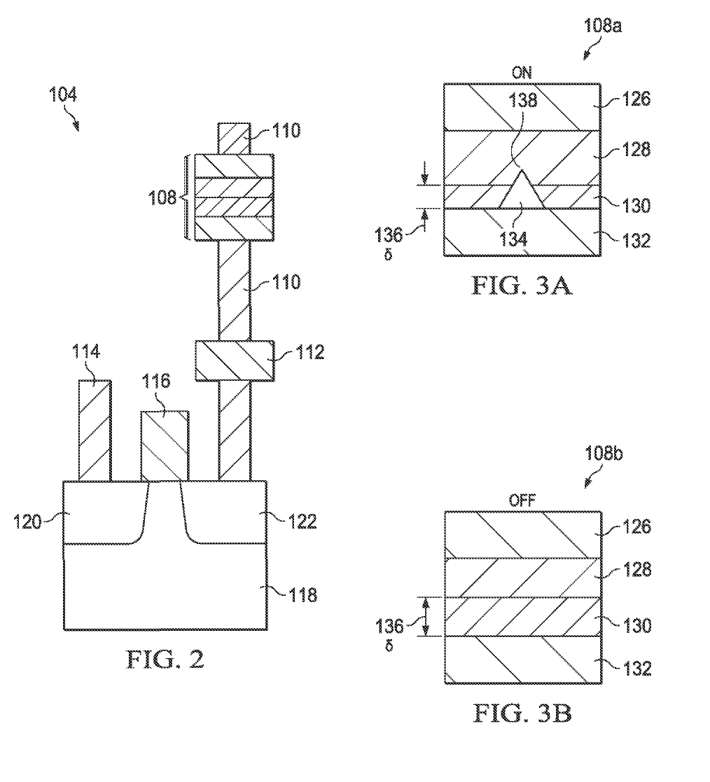

Turning to FIG. 2, FIG. 2 illustrates one embodiment of transistor 104. Transistor 104 can include RRAM 108, a bit line 110, contact 112, a source 114, a gate 116, a substrate 118, a source junction 120, and drain junction 122. RRAM 108 may be a conductive bridge RRAM where the term “conductive bridge RRAM” includes a special kind of RRAM where the active element that participates the resistance change is a conductive bridge of metal ions. In an example, bit line 110 can be a contact to RRAM 108. Contact 112 can be a metal connection for transistor 104. More specifically, contact 112 can be part of a metal-2 or metal-3 extended connection.

Bit line 110 may be a top electrode or bit line. Source 114 and gate 116 may each be configured as a word line. Substrate 118 can be a silicon base substrate. Transistor 104 can be configured to allow access to RRAM 108 and change the resistance of RRAM 108. For example, transistor 104 can be configured to program RRAM 108, deselect or not disturb RRAM 108, read RRAM 108, etc.

Gate 116 can include a gate metal and a dielectric. The gate metal may be a gate electrode and dielectric may be a gate oxide. The dielectric can be configured to help ensure that there is no current, or that an applied a current or bias on gate 116 is allowed to open a channel between source junction 120 and drain junction 122. When the channel is opened, a SET current can flow through source junction 120 and drain junction 122. When the bias is removed from gate 116 the channel is removed and the SET current ceases to flow. Drain junction 122 can be insulating to help to ensure there is not leakage from source 114 into substrate 118.

In a typical filamentary RRAM, an insulating medium is in between a top electrode and a bottom electrode. A filament is created in the insulating medium between the bottom electrode and the top electrode by applying a bias and flowing current through the bottom electrode. In a typical on state, there is a continuous filament that connects both the bottom and top electrode and because it connects both, the RRAM is a low resistance state. For a high resistance state or an off state, the filament is broken but the gap between the tip of filament and the top electrode is hard to control so a batch of currently produced filamentary RRAM will have a large variability in the off state. For example, with 1 million bits in an array, some will have a very high resistance and a large gap while others will have a much lower resistance and a lower gap and consistency between currently produced filamentary RRAM is difficult to maintain.

In a typical interfacial RRAM, the resistance is defined by controlling the composition between the interface of the electrode and the insulating medium. The interface is engineered such that by applying a bias, in similar manner as the filamentary RRAM, the interfacial region is engineered to change from a thin region to a thick region. Typically, there is a much more uniform distribution compared to the filamentary RRAM in the in the low resistance and high resistance state. However, the problem with interfacial RRAM is that the resistance values are much higher than the filamentary RRAM. It would be beneficial to create a RRAM with a low resistance state like the filamentary RRAM exhibits with a low bias and a high resistance state like the interfacial RRAM with a high bias. This would allow for consistency between RRAM, for a uniform distribution, and a large window between the high and low biases. RRAM 108 can be configured as an interfacial RRAM stack that can create a partial filament that will only break through the interfacial layer when transistor 104 is biased on.

In one implementation, RRAM 108 can acquire its resistance by applying a bias which is created by running a current through bit line 110. Typically, a bi-polar RRAM is used where a positive bias turns on the RRAM (i.e., a SET) and a negative bias turns off the RRAM (i.e., a RESET). To bias transistor 104, an electrical connection can be coupled to bit line 110, source 114, and gate 116.

In order to bias transistor 104 and set RRAM 108, or turn RRAM 108 from an “off state” to an “on state,” a positive bias needs to be applied to RRAM 108. To achieve this, a positive voltage on bit line 110 can be biased positively with a high voltage. In the case of an NMOS transistor, gate 116 has to be biased positive and source 114 does not see any bias or would be biased to zero. In this example, source 114 would turn on transistor 104 based on the difference between the voltages on gate 116 and source 114. In this biasing condition, RRAM 108 does not interfere and the voltage to turn on transistor 104 is the voltage on source 114 and gate 116. Once transistor 104 is turned on, its resistance is lowered significantly and most of the voltage applied to gate 116 will be used by RRAM 108. By enabling transistor 104 to turn on with a low source voltage (Vs), the configuration of transistor 104 helps ensure that RRAM 108 sees most of the applied voltage to successfully program RRAM 108 or cause RRAM 108 to change its resistance. To turn the resistance off from a low resistance to a high resistance, different biases can be applied to bit line 110, source 114, and gate 116. For example, source 114 would be a positive bias to turn on a NMOS transistor. Gate 116, would be biased to a positive voltage. Bit line 110 would be biased to zero.

Turning to FIG. 3A, FIG. 3A illustrates one embodiment RRAM 108 in an on state. In a specific implementation, RRAM 108a is in an on state and can include a top electrode 126, an upper interfacial region 128, a modulated interfacial region 130, and bottom electrode 132. Bottom electrode 132 can be an active electrode that is a source for metal ions that provide the metal atoms for the creation of a filament 134. In an example, upper interfacial region 128 can be below top electrode 126 (or top electrode 126 can be on upper interfacial region 128), modulated interfacial region 130 can be below upper interfacial region 128 (or upper interfacial region 128 can be on modulated interfacial region 130), and bottom electrode 132 can be below modulated interfacial region 130 (or modulated interfacial region 130 can be on bottom electrode 132).

In an example, interfacial region 128 and modulated interfacial region 130 of RRAM 108a are similar to an interfacial RRAM. More specifically, modulated interfacial region 130 is an interfacial region similar to an interfacial region of and interfacial RRAM. For example, a width of modulated interfacial region 130 can be modulated from a first width to a second width and the back to the first width (e.g., as illustrated in FIGS. 3A and 3B). Bottom electrode 132 can contribute electrodes to interfacial region 128 and modulated interfacial region 130 to create filament 134. More specifically, bottom electrode 132 can contribute or inject metal atoms into interfacial region 128 and modulated interfacial region 130. The metal atoms can be used to create filament 134. In an illustrative example, when RRAM 108a is in an on state, RRAM 108a has an interfacial region (e.g., interfacial region 128 and modulated interfacial region 130) similar to an interfacial RRAM. However, RRAM 108a also includes filament 134 that is breaking through modulated interfacial region 130 so the resistance between top electrode 126 and bottom electrode 132 is relatively low and is not defined by a thickness 136 of modulated interfacial region 130 as in an interfacial RRAM where there is a high resistance. In this example, the resistance is more similar to a filament RRAM.

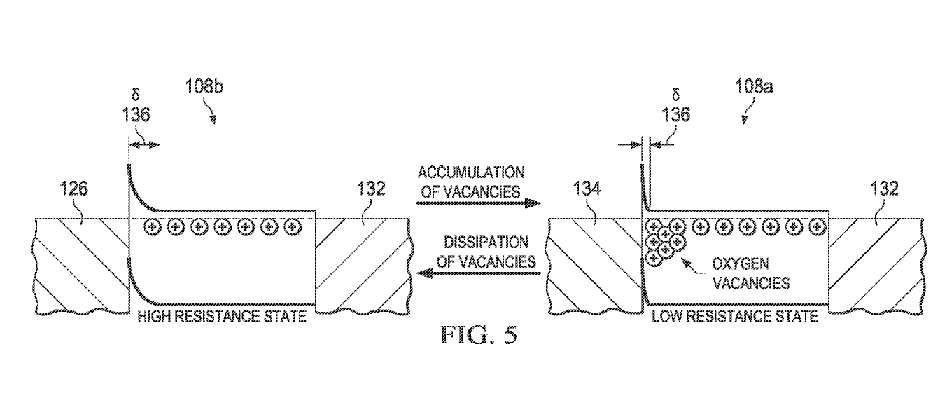

Turning to FIG. 3B, FIG. 3B illustrates one embodiment of RRAM 108 in an off state. In a specific implementation, RRAM 108b is in an off state and can include top electrode 126, upper interfacial region 128, modulated interfacial region 130, and bottom electrode 132. In the off state, filament 134 (illustrated in FIG. 3A) has been dissolved and thickness 136 of modulated interfacial region 130 is increased to approximate the thickness and resistance of an interfacial RRAM in an off state. In an example, as illustrated below in FIG. 5, modulation of modulated interfacial region 130 can be achieved by moving ions closer and further away from an electrode interface based on the biasing conditions. The ions are usually charged (such as positively charged oxygen vacancies) and move under bias as illustrated in FIG. 5. This allows RRAM 108 to have a relatively low resistance in the on state, similar to a filament RRAM and a relatively high resistance in the off state, similar to an interfacial RRAM.

In an example, the filament creation and dissolution is during the application of the voltage on RRAM 108 (i.e., during the programing of RRAM 108). Bottom electrode 132 can be an active electrode (e.g., a metal source electrode) that includes the material that can be used to create filament 134. For example, to create a filament of copper, bottom electrode 132 can include copper (e.g., a copper (Cu) electrode, an alloy such as cooper and germanium (CuGe), copper, germanium, sulfide (Cu2GeS3), etc.) to create a filament of silver, bottom electrode 132 can include silver (e.g., a silver (Ag) electrode or an alloy such as silver selenium (Ag2Se), silver sulfide (Ag2S), etc.). When a bias is applied on bottom electrode 132, an electro chemical cell is created that dissolves the metal in bottom electrode 132 into modulated interfacial region 130. The dissolved metal can grow and create filament 134 which allows for a low resistance path between top electrode 126 and bottom electrode 132. The creation of filament 134 can be configured based on a desired creating time, height, etc. by modifying the composition of bottom electrode 132. For example, modulated interfacial region 130 and bottom electrode 132 can be configured so filament 134 can break through modulated interfacial region 130 into upper interfacial region 128 in 1 micro second at 1 volt of operating voltage. In the reverse polarity (for RESET operation), the bias is switched from bottom electrode and filament 134 can be dissolved from modulated interfacial region 130 and redeposited onto bottom electrode 132.

By engineering the materials in modulated interfacial region 130 (e.g., indium gallium zinc oxide (InGaZnO), yttrium zirconium oxide (YZrO), titanium oxide (TiOx), etc.) and upper interfacial region 128 (e.g., aluminum oxide (AlOx), gadolinium oxide (GdOx), silicon oxide (SiOx), etc.) in combination with bottom electrode 132 that forms an ion source (e.g., copper tellurium (CuTe), CuGe, zirconium tellurium (ZrTe), hydrogen fluoride tellurium (HfTe), Silver sulfide (AgS), etc.), RRAM 108 can be configured with tunable performance, variability and reliability. As a result, the performance and reliability of RRAM 108 can be increased and may be used as e-NVM. Bottom electrode 132 can be configured with a tunable depletion width to control resistance and to control the creation of filament 134. In an example, modulated interfacial region 130 and upper interfacial region 128 can be about 1 nanometer (nm) to about −20 nm thick. Modulated interfacial region 130 and upper interfacial region 128 can include silicon oxide (SiOx) or an alloy of SiOx, aluminum oxide (AlOx) or an alloy of AlOx, tantalum oxide (TaO) or an alloy of TaO, flourous oxide (HfOx) or an alloy of HfOx, germanium sulfide (GeS) or an alloy of GeS, germanium oxide (GeOx) or an alloy of GeOx, titanium oxide (TiOx) or an alloy of TiOx, lanthanum oxide (LaOx) or an alloy of LaOx, or some other similar material.

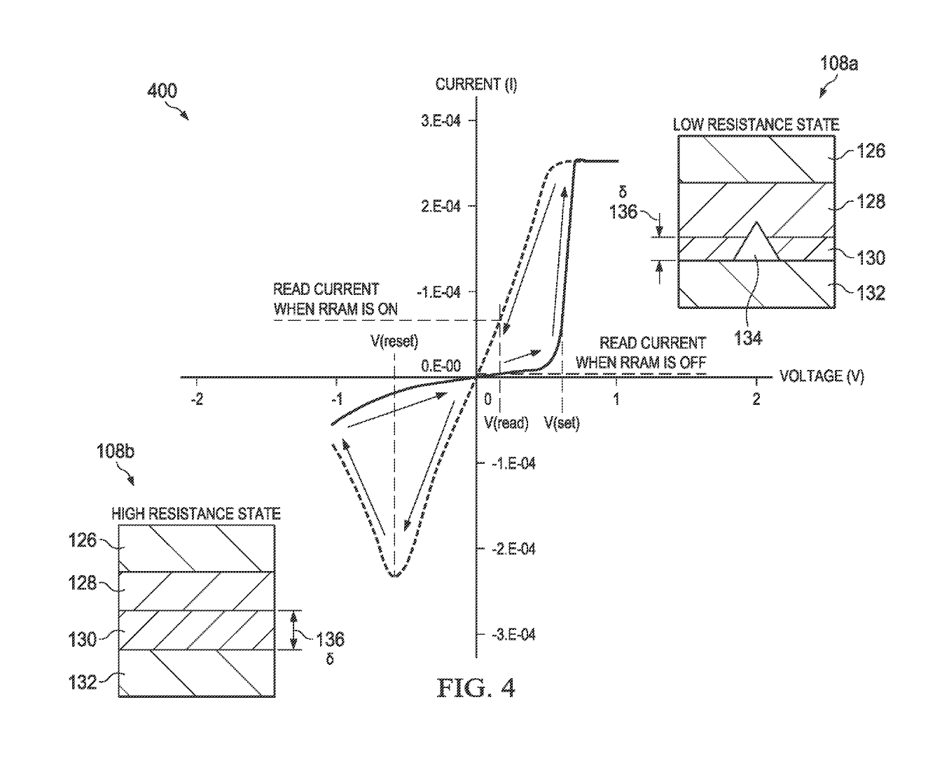

Turning to FIG. 4, FIG. 4 is a simplified graph illustrating example details associated with an embodiment of an electronic device, in accordance with one embodiment of the present disclosure. As illustrated in FIG. 4, when RRAM 108 is in a low resistive state (e.g., RRAM 108a), filament 134 is created and RRAM 108 has the characteristics of a filamentary RRAM where a relative large amount of current can be created using a relatively small amount of voltage. Also, when RRAM 108 is in a high resistive state (e.g., RRAM 108b), filament 134 is not present and thickness 136 of modulated interfacial region 130 is similar to an interfacial RRAM where there is a high resistance between top electrode 126 and bottom electrode 132. In addition, a large window is created between the low and high resistive states and the large window can provide for multi-state RRAM such as off or low, medium or half, and on or high. When RRAM switches from off (high resistance state) to on (low resistance state) the bias is positive (and goes beyond Vset) on the bit line. For the reset operation, the biasing conditions are switched as illustrated by the arrows in the negative voltage quadrant going from where RRAM is on to where RRAM is off (after the voltage goes beyond Vreset). At the Vread bias, there are two read out currents. If RRAM 108 is on (e.g., RRAM 108a), there is a high current and when RRAM 108 is off (e.g., RRAM 108b), there is a low read current.

Turning to FIG. 5, FIG. 5 is a simplified block diagram diagram illustrating example details associated with an embodiment of a portion of an electronic device, in accordance with one embodiment of the present disclosure. As illustrated in FIG. 5, in a low resistive state (e.g., RRAM 108a), thickness 136 of modulated interfacial region 130 is relatively low and the configuration of RRAM 108a allows for the formation of oxygen vacancies. This formation (or accumulation) of oxygen vacancies allows for the modulation of interfacial region 130 and the metal in bottom electrode 132 to be injected into interfacial region 128 and modulated interfacial region 130 where the metal atoms can be used to create filament 134. In a high a high resistive state (e.g., RRAM 108b), thickness 136 of modulated interfacial region 130 is similar to an interfacial RRAM in a high resistive state. Modulated interfacial region 130 allows for a dissipation of oxygen vacancies allowing the metal from bottom electrode 132 to return or dissipate back into bottom electrode and dissolve filament 134.

The semiconductor substrate for substrate 118 (and any additional layers) may be formed using alternate materials, which may or may not be combined with silicon. This includes, but is not limited to, germanium, indium antimonide, lead telluride, indium arsenide, indium phosphide, gallium arsenide, indium gallium arsenide, gallium antimonide, or other combinations of group III-V or group IV materials. In other examples, the substrate of any layer may be a flexible substrate including 2D materials such as graphene and MoS2, organic materials such as pentacene, transparent oxides such as IGZO poly/amorphous (low temperature of dep) III-V semiconductors and Ge/Si, and other non-silicon flexible substrates.

In an example, a plurality of electrical components can include one or more transistors 104 and/or one or more arrays 106. In addition, a plurality of transistors, such as MOSFET or simply MOS transistors), can include one or more transistors 104, may be fabricated on the substrate. In various embodiments, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that various embodiments may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type work function metal or N-type work function metal, depending on whether the transistor is to be a PMOS or an NMOS transistor. In some implementations, the gate electrode layer may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a work function that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a work function that is between about 3.9 eV and about 4.2 eV.

In some implementations, when viewed as a cross-section of the transistor along the source-channel-drain direction, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

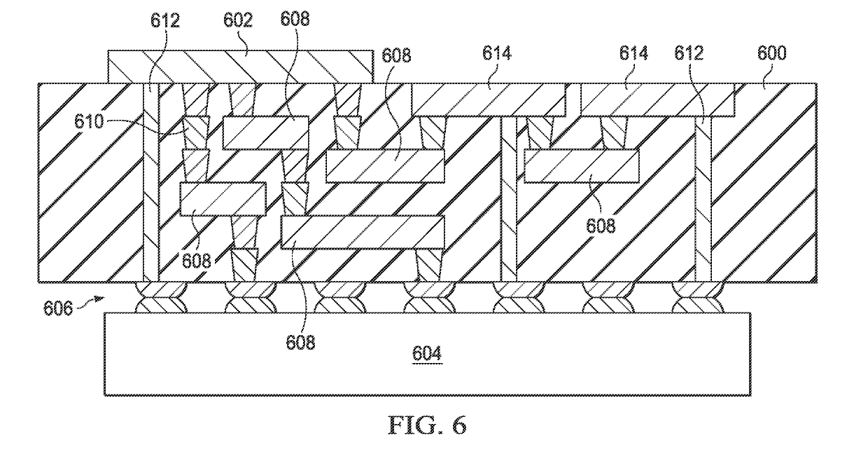

Turning to FIG. 6, FIG. 6 illustrates an interposer 600 that can include or interact with one or more embodiments disclosed herein. The interposer 600 is an intervening substrate used to bridge a first substrate 602 to a second substrate 604. The first substrate 602 may be, for instance, an integrated circuit die. The second substrate 604 may be, for instance, a memory module, a computer motherboard, or another integrated circuit die. Generally, the purpose of an interposer 600 is to spread a connection to a wider pitch or to reroute a connection to a different connection. For example, an interposer 600 may couple an integrated circuit die to a ball grid array (BGA) 606 that can subsequently be coupled to the second substrate 604. In some embodiments, the first and second substrates 602/604 are attached to opposing sides of the interposer 600. In other embodiments, the first and second substrates 602/604 are attached to the same side of the interposer 600. And in further embodiments, three or more substrates are interconnected by way of the interposer 600.

The interposer 600 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 608 and vias 610, including but not limited to through-silicon vias (TSVs) 612. The interposer 600 may further include embedded devices 614, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 600. In accordance with various embodiments, apparatuses or processes disclosed herein may be used in the fabrication of interposer 600.

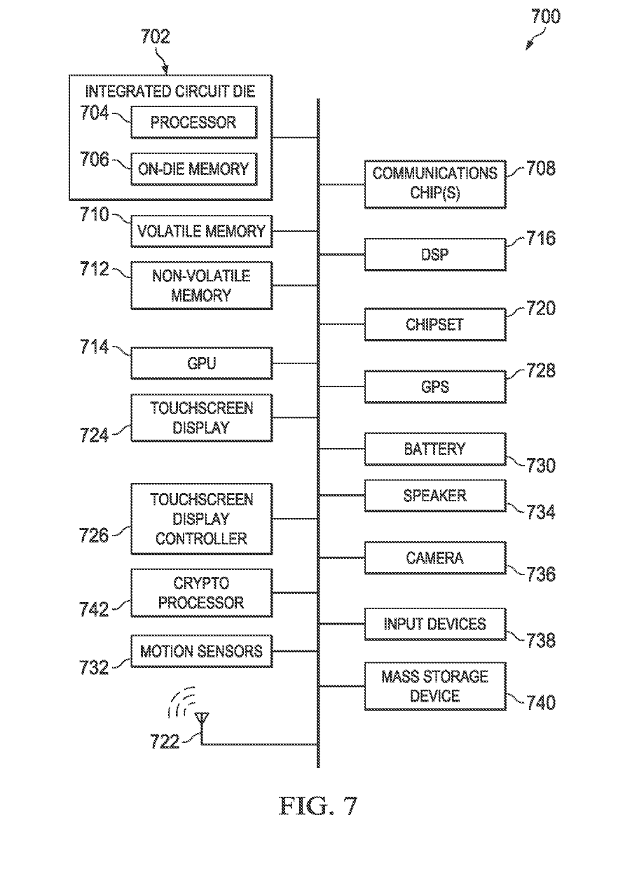

Turning to FIG. 7, FIG. 7 illustrates a computing device 700 in accordance with various embodiments. The computing device 700 may include a number of components. In one embodiment, these components are attached to one or more motherboards. In an alternate embodiment, some or all of these components are fabricated onto a single system-on-a-chip (SoC) die. The components in the computing device 700 include, but are not limited to, an integrated circuit die 702 and at least one communications logic unit 708. In some implementations the communications logic unit 708 is fabricated within the integrated circuit die 702 while in other implementations the communications logic unit 708 is fabricated in a separate integrated circuit chip that may be bonded to a substrate or motherboard that is shared with or electronically coupled to the integrated circuit die 702. The integrated circuit die 702 may include a CPU 704 as well as on-die memory 706, often used as cache memory, that can be provided by technologies such as embedded DRAM (eDRAM) or spin-transfer torque memory (STTM or STT-M RAM).

Computing device 700 may include other components that may or may not be physically and electrically coupled to the motherboard or fabricated within an SoC die. These other components include, but are not limited to, volatile memory 710 (e.g., DRAM), non-volatile memory 712 (e.g., ROM or flash memory), a graphics processing unit 714 (GPU), a digital signal processor 716, a crypto processor 742 (a specialized processor that executes cryptographic algorithms within hardware), a chipset 720, an antenna 722, a display or a touchscreen display 724, a touchscreen controller 726, a battery 728 or other power source, a power amplifier (not shown), a voltage regulator (not shown), a global positioning system (GPS) device 728, a compass 730, a motion coprocessor or sensors 732 (that may include an accelerometer, a gyroscope, and a compass), a speaker 734, a camera 736, user input devices 738 (such as a keyboard, mouse, stylus, and touchpad), and a mass storage device 740 (such as hard disk drive, compact disk (CD), digital versatile disk (DVD), and so forth).

The communications logic unit 708 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communications logic unit 708 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communications logic units 708. For instance, a first communications logic unit 708 may be dedicated to shorter range wireless communications such as Wi-Fi and Bluetooth and a second communications logic unit 708 may be dedicated to longer range wireless communications such as GPS, EDGE, GPRS, CDMA, WiMAX, LTE, Ev-DO, and others.

The processor 704 of the computing device 700 can communicate with one or more devices that are formed in accordance with various embodiments. The term “processor” may refer to any device or portion of a device that processes electronic data from registers and/or memory to transform that electronic data into other electronic data that may be stored in registers and/or memory.

The communications logic unit 708 may also include one or more devices, such as transistors or metal interconnects, that are in communication with various ones of the embodiments disclosed herein. In further embodiments, another component housed within the computing device 700 may contain one or more devices, such as transistors or metal interconnects, that are formed in accordance with implementations of the embodiments disclosed herein.

In various embodiments, the computing device 700 may be a laptop computer, a netbook computer, a notebook computer, an ultrabook computer, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 700 may be any other electronic device that processes data.

The above description of illustrated implementations, including what is described in the Abstract, is not intended to be exhaustive or to limit the scope of the disclosure to the precise forms disclosed. While specific implementations of, and examples for, the embodiments disclosed herein are described herein for illustrative purposes, various equivalent modifications are possible within the scope of the disclosure, as those skilled in the relevant art will recognize.

### OTHER NOTES AND EXAMPLES

Example 1 is an apparatus including a top electrode, an upper interfacial region below the top electrode, a modulated interfacial region below the upper interfacial region, and a bottom electrode below the modulated interfacial region. The bottom electrode can be an active electrode that is a source for metal ions for the creation of a filament between the top electrode and the bottom electrode.

In Example 2, the subject matter of Example 1 can optionally include where the apparatus is a transistor.

In Example 3, the subject matter of any one of Examples 1 and 2 can optionally include where the transistor includes resistive random access memory (RRAM).

In Example 4, the subject matter of any one of Examples 1-3 can optionally include where the filament is created when the transistor is in an on state.

In Example 5, the subject matter of any one of Examples 1-4 can optionally include where the filament is not present when the transistor is in an off state.

In Example 6, the subject matter of any one of Examples 1-5 can optionally include where the filament is created when a positive bias is applied to the bottom electrode.

In Example 7, the subject matter of any one of Examples 1-6 can optionally include where the filament dissolves into the bottom electrode when a negative bias is applied to the bottom electrode.

In Example 8, the subject matter of any one of Examples 1-7 can optionally include where a thickness of the modulated interfacial region is modulated between an on state thickness and an off state thickness.

In Example 9, a method can include causing a transistor to operate in a first state, where the transistor includes a top electrode, an upper interfacial region, a modulated interfacial region, and a bottom electrode. The bottom electrode can be an active electrode below the modulated interfacial region and is a source for metal ions for the creation of a filament between the top electrode and the bottom electrode.

In Example 10, the subject matter of Example 9 can optionally include causing the transistor to operate in a second state, where the filament is not present when the transistor is in the second state.

In Example 11, the subject matter of any one of Examples 9 and 10 can optionally include where he transistor includes resistive random access memory (RRAM).

In Example 12, the subject matter of any one of Examples 9-11 can optionally include where a thickness of the modulated interfacial region is modulated between a first state thickness when the transistor is in the first state and a second state thickness when the transistor is in the second state.

In Example 13, the subject matter of any one of Examples 9-12 can optionally include where the filament is created when a positive bias is applied to the bottom electrode.

In Example 14, the subject matter of any one of Examples 9-13 can optionally include where the filament dissolves into the bottom electrode when a negative bias is applied to the bottom electrode.

In Example 15, the subject matter of any one of Examples 9-14 can optionally include where the first state occurs when a positive bias is applied to the transistor and the second state occurs when a negative bias is applied to the transistor

Example 16 is a computing device including a processor mounted on a substrate, a communications logic unit within the processor, a memory within the processor, a graphics processing unit within the computing device, an antenna within the computing device, a display on the computing device, a battery within the computing device, a power amplifier within the processor, and a voltage regulator within the processor. The memory can include a transistor and the transistor can include a top electrode, an upper interfacial region, a modulated interfacial region, and a bottom electrode below the modulated interfacial region. The bottom electrode can be an active electrode that is a source for metal ions for the creation of a filament between the top electrode and the bottom electrode.

In Example 17 the subject matter of Example 16 can optionally include where the memory includes resistive random access memory (RRAM).

In Example 18 the subject matter of any one of Examples 16 and 17 can optionally include where the filament is created when the transistor is in an on state.

In Example 19, the subject matter of Example 16-18 can optionally include where the filament is not present when the transistor is in an off state.

In Example 20, the subject matter of any one of the Examples 16-19 can optionally include where a thickness of the modulated interfacial region is modulated between an on state thickness and an off state thickness.

In Example 21, the subject matter of any one of the Examples 16-20 can optionally include where the filament dissolves into the bottom electrode when a negative bias is applied to the bottom electrode.

Example 22 is an integrated circuit (IC) assembly including a substrate, a source on top of the substrate, a gate on top of the substrate, and a drain on top of the substrate, where the drain includes a top electrode, an upper interfacial region, a modulated interfacial region, and a bottom electrode. The bottom electrode can be an active electrode that is a source of metal ions for the creation of a filament between the top electrode and the bottom electrode.

In Example 23, the subject matter of Example 22 can optionally include where the filament is created when a positive bias is applied to the bottom electrode.

In Example 24, the subject matter of any one of the Examples 22 and 23 can optionally include where the filament is not present when a negative bias is applied to the bottom electrode.

In Example 25, the subject matter of any one of the Examples 22-24 can optionally include where a thickness of the modulated interfacial region is modulated between an on state thickness and an off state thickness.

In Example, 26, the subject matter of any one of the Examples 1-8 can optionally include where biasing conditions of the transistor are used to modulate the thickness of the modulated interfacial region.

In Example, 27, the subject matter of any one of the Examples 9-15 can optionally include where biasing conditions of the transistor are used to modulate the thickness of the modulated interfacial region.

In Example, 28, the subject matter of any one of the Examples 16-21 can optionally include where biasing conditions of the transistor are used to modulate the thickness of the modulated interfacial region.

In Example, 29, the subject matter of any one of the Examples 22-25 can optionally include where biasing conditions of the transistor are used to modulate the thickness of the modulated interfacial region.

1-25. (canceled)

26. A memory device, comprising:
a first electrode;
a second electrode;
a conductive oxide between the first electrode and the second electrode; and
a resistive oxide between the conductive oxide and the second electrode.

27. The memory device of claim 26, wherein the conductive oxide includes indium, gallium, zinc, yttrium, zirconium, or titanium.

28. The memory device of claim 27, wherein the conductive oxide includes indium, gallium, and zinc.

29. The memory device of claim 27, wherein the conductive oxide includes yttrium and zirconium.

30. The memory device of claim 27, wherein the conductive oxide includes titanium.

31. The memory device of claim 26, wherein the resistive oxide includes aluminum, gadolinium, or silicon.

32. The memory device of claim 26, wherein the first electrode or the second electrode includes copper, tellurium, germanium, zirconium, hafnium, silver, or sulfur.

33. The memory device of claim 32, wherein the first electrode or the second electrode includes copper and tellurium.

34. The memory device of claim 32, wherein the first electrode or the second electrode includes copper and germanium.

35. The memory device of claim 32, wherein the first electrode or the second electrode includes zirconium and tellurium.

36. The memory device of claim 32, wherein the first electrode or the second electrode includes hafnium and tellurium.

37. The memory device of claim 32, wherein the first electrode or the second electrode includes silver and sulfur.

38. The memory device of claim 26, wherein the memory device is a resistive random access memory (RRAM) device.

39. An integrated circuit (IC) die, comprising:
a memory cell including a transistor coupled to a resistive random access memory (RRAM) device, wherein the RRAM device includes a layer of conductive oxide and a layer of resistive oxide between a first electrode and a second electrode.

40. The IC die of claim 39, comprising an array of multiple memory cells.

41. The IC die of claim 39, wherein a source/drain of the transistor is coupled to the second electrode.

42. A computing device, comprising:
a processing device; and
a memory communicatively coupled to the processing device, wherein the memory includes a memory cell, and the memory cell includes:
a first electrode;
a second electrode;
a first material between the first electrode and the second electrode; and
a second material between the first material and the second electrode;
wherein the first material includes indium, gallium, zinc, and oxygen; yttrium, zirconium, and oxygen; or titanium and oxygen; and
wherein the second material includes aluminum and oxygen, gadolinium and oxygen, or silicon and oxygen.

43. The computing device of claim 42, wherein the first electrode or the second electrode includes copper and tellurium; copper and germanium; zirconium and tellurium; hafnium and tellurium; or silver and sulfur.

44. The computing device of claim 42, further comprising:
a circuit board, wherein the processing device is coupled to the circuit board.

45. The computing device of claim 42, wherein the computing device is a handheld computing device or a server computing device.
